(19) United States
(12) Patent Application Publication
(10) Pub. No.: US 2019/0252566 A1
(43) Pub. Date: Aug. 15, 2019

(54) Solar Energy Device

(71) Applicants: Steven J. Malone, Manti, UT (US); Hyrum S. Malone, Manti, UT (US)

(72) Inventors: Steven J. Malone, Manti, UT (US); Hyrum S. Malone, Manti, UT (US)

(21) Appl. No.: 15/896,061

(22) Filed: Feb. 14, 2018

(51) Int. Cl. H01L 31/054; F24S 30/40; F24S 23/71

(52) U.S. Cl. CPC H01L 31/0547; F24S 23/71; F24S 30/40

(57) ABSTRACT

A solar energy device includes a first parabolic reflector and a second parabolic reflector. The first parabolic reflector reflects sunlight into the second parabolic reflector and the second parabolic reflector reflects substantially all of the sunlight through an opening in the first parabolic reflector. The sunlight is directed into a first heat exchanger behind the first parabolic reflector. Solar energy cooking devices and systems are also disclosed.

### BACKGROUND

### Field of the Invention

The present invention is related to solar energy devices and solar energy cooking systems.

### SUMMARY

A solar device includes a first parabolic reflector and a second parabolic reflector. The first parabolic reflector reflects sunlight into the second parabolic reflector and the second parabolic reflector reflects substantially all of the sunlight through an opening in the first parabolic reflector. The sunlight is directed into a first heat exchanger behind the first parabolic reflector. Solar energy cooking devices and systems are also disclosed.

The solar device may further comprise a heat exchanger. The heat exchanger may contain material for retaining, storing, or transferring heat. The solar device may be used to cook food, heat water, or sterilize water. The solar device may be used to sterilize objects. The solar device may further comprise one or more heat transfer lines. The first parabolic reflector may be larger in overall size than the second parabolic reflector. The first solar reflector may track the sunlight such that temperature within a heat exchanger is controlled. The tracking may be 2-axis tracking. The first solar reflector may be attached to a rotating base and two side supports, the rotating base forming a first axis of rotation and the two side supports forming a second axis of rotation. Each axis of rotation may be independently controlled by a first motor and a second motor. The first motor or the second motor may be rotated to control a temperature within the heat exchanger. One or more heat transfer lines may connect to: a barbeque grill, a smoker, a dehydrator, a kettle, a pot, a coffee maker, a stove, a toaster oven, a pizza oven, a bread oven, a warmer, a steam cooker, a solar still, an incubator, a kiln, a sanitizer cabinet, or an autoclave. The heat exchanger may form a surface for cooking or transferring heat to a cooking device or container. The solar device may further comprise a cooking container. The solar device may provide heat for cooking, purifying water, sanitizing, or starting fires. The solar device may further comprise a shutter between the first parabolic reflector and the heat exchanger. The solar device may further comprise an optically transparent element behind, inside, or near the opening in the first parabolic reflector. The heat exchanger may be a cooking container. The first parabolic reflector may be mechanically connected to the cooking container.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 shows a solar energy device in accordance with an embodiment of the invention;

FIG. 2 shows a solar energy device in accordance with an embodiment of the invention;

FIG. 3 shows a solar energy device in accordance with an embodiment of the invention;

FIG. 4 shows a solar energy device in accordance with an embodiment of the invention;

FIG. 5 shows a solar energy device in accordance with an embodiment of the invention;

FIG. 6 shows a solar energy device in accordance with an embodiment of the invention; and

FIG. 7 shows a solar energy device in accordance with an embodiment of the invention.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings.

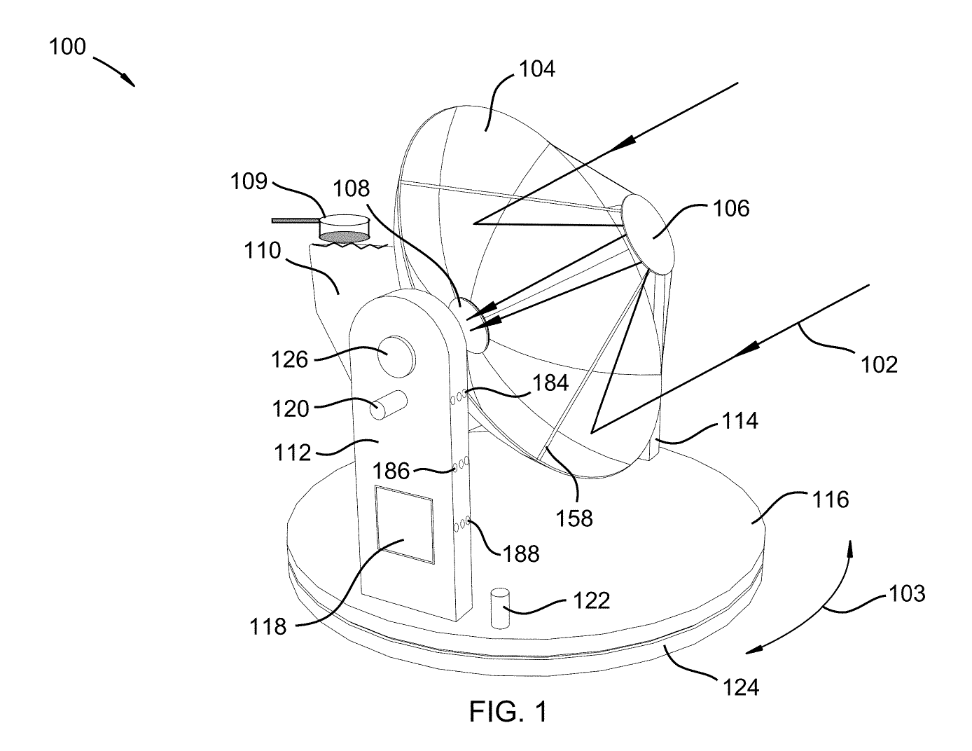

FIG. 1 shows a solar energy cooking device 100 including first parabolic reflector 104, second parabolic reflector 106, first heat exchanger 110, first rotational axis 103, electrical control center 118, optical sensors 184, photovoltaic cells 186/188, motors 120/122, top base plate 116, bottom base plate 124, side supports 112/114, rotational pivot 126, incident sunlight 102, aperture 108, and supports 158. Sunlight 102 is reflected off of first parabolic reflector 104 into second parabolic reflector 106 at or near a focal point of first parabolic reflector 104. It may be beneficial to position second parabolic reflector 106 behind or in front of an exact focal point of parabolic reflector 104 to evenly distribute light energy across second parabolic reflector 106. Second parabolic reflector 106 reflects substantially all of the reflected energy through aperture 108 of first parabolic reflector 104. Aperture 108 may be larger than a beam size of energy reflected in order to protect surfaces of first parabolic reflector 104. Heat exchanger 110 may be directly connected to first parabolic reflector 104 or may be remote or removed by a designed gap. Top base plate 116 may rotate in relation to bottom base plate 124. Motor 122 may provide force necessary to or rotate top plate 116. Bearings and gearing may be found between top plate 116 and bottom plate 124. Sensors 184 may detect an angular position of the sun based on intensity readings of an array of sensors 184, 186, 188 or by one or more of the sensors of the array. Electrical control center 118 may include a rechargeable battery, control circuitry, one or more microprocessors, memory, and programming. Electrical control center 118 may provide motor control for motors 120 and 122. Photovoltaic cells 186/188 may provide energy to charge a battery, power control center 118, and may provide one or more intensity inputs to control center 118 for determining an angular position of the sun relative to the first parabolic reflector 104. Side supports 112/114 provide structural support for the first and second parabolic reflectors 104/106. Rotational pivot 126 allows first parabolic reflector 104 to rotate in a vertical motion while rotational axis allows first parabolic reflector 104 to rotate in a horizontal direction. Heat exchanger 110 directs heat produced by rays 102 to cooking pot 109. The concentrated light energy may be optically reflected to the bottom surface of cooking pot 109 or may be transferred by way of heat conduction to a surface that cooking pot 109 rests on. Heat produced by concentrated light energy may be absorbed by heat conducting materials such as water, brick, metal, metal micro-beads, ceramic, or air. Other materials such as copper heat sinks, aluminum heat sinks, or direct contact metal surfaces may be used to transfer heat from light energy 102 to cooking pot 109. Heat exchanger 110 may be mechanically connected or mechanically disconnected from first parabolic reflector 104. Control center 118 includes motor control drivers, logic programming, analog temperature inputs, analog light intensity inputs, temperature control algorithms, digital inputs, computer programming, memory, and safety circuitry allowing for safe temperature and motion control systems. Control center 118 may receive a temperature input from one or more temperature sensors associated with a cooking surface of cooking pot 109 and/or associated with heat exchanger 110. Control center 118 may cause first parabolic reflector 104 to move relative to an angle of incidence of light energy 102 in order to control heat applied to cooking pot 109. A shutter may be positioned between heat exchanger 110 and first reflector 104 and be controlled by control center 118. When the shutter is closed light energy 102 is blocked from entering aperture 108 and may be reflected away from first parabolic reflector 104 and second parabolic reflector 106. The shutter may have a convex surface which faces a concave surface of second parabolic reflector 106.

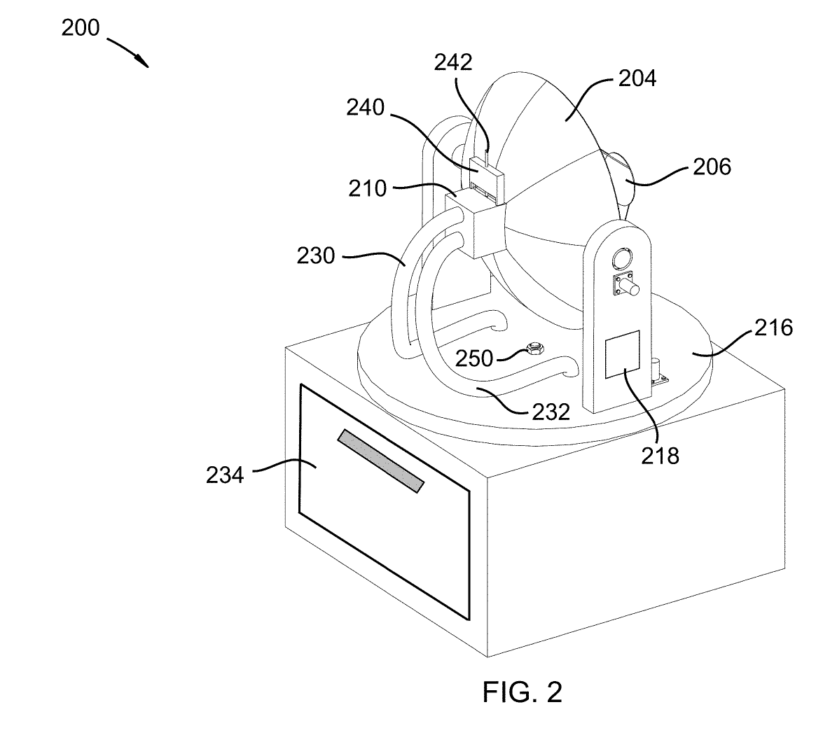

FIG. 2 shows a solar energy device 200 including shutter housing 240, shutter actuator rod 242, heat transfer lines 230/232, first parabolic reflector 204, second parabolic reflector 206, heat exchanger 210, controlled temperature unit 234, and fastener 250. Shutter rod 242 may be used to control temperature inside of heat exchanger 210 and/or the controlled temperature unit 234. Control system 218 may receive temperature readings from one or more temperature sensors associated with heat exchanger 210 and controlled temperature unit 234 and may open or close shutter rod 242 causing light energy to be reflected out and away from both of first parabolic reflector 204 and second parabolic reflector 206. Additionally and/or alternatively temperature inside of controlled temperature unit 234 and/or heat exchanger 210 may be controlled by rotating the first parabolic reflector toward or away from an orthogonal direction of incident sunlight. Toward an orthogonal direction to increase temperature and away from an orthogonal direction to decrease temperature. Controlled temperature unit 234 may be a stove, toaster oven, pizza oven, bread oven, warmer, steam cooker, solar still, incubator, kiln, sanitizer cabinet, or autoclave. In some embodiments, controlled temperature unit 234 may be generally thought of as a food container. Heat exchanger 210 may be mechanically connected or mechanically disconnected from first parabolic reflector 204. A fan may circulate heated air or other fluids through heat exchanger 210, heat transfer lines 230/232, and controlled temperature unit 234 such that heat is transferred between heat exchanger 210 and controlled temperature unit 234. Control center 218 includes motor control drivers, logic programming, analog temperature inputs, analog light intensity inputs, temperature control algorithms, digital inputs, computer programming, memory, and safety circuitry allowing for safe temperature and motion control systems. Control center 218 may receive a temperature input from one or more temperature sensors associated with controlled temperature unit 234 and/or associated with heat exchanger 210. Control center 218 may cause first parabolic reflector 204 to move relative to an angle of incidence of light energy in order to control heat applied to controlled temperature unit 234. Control center 218 may control a volume of forced air or fluids in order to control temperatures inside of controlled temperature unit 234. A shutter 240/242 may be positioned between heat exchanger 210 and first reflector 204 and be controlled by control center 218. When the shutter is closed light energy is blocked from entering heat exchanger 210 and may be reflected away from first parabolic reflector 204 and second parabolic reflector 206. The shutter may have a convex surface which faces a concave surface of second parabolic reflector 206.

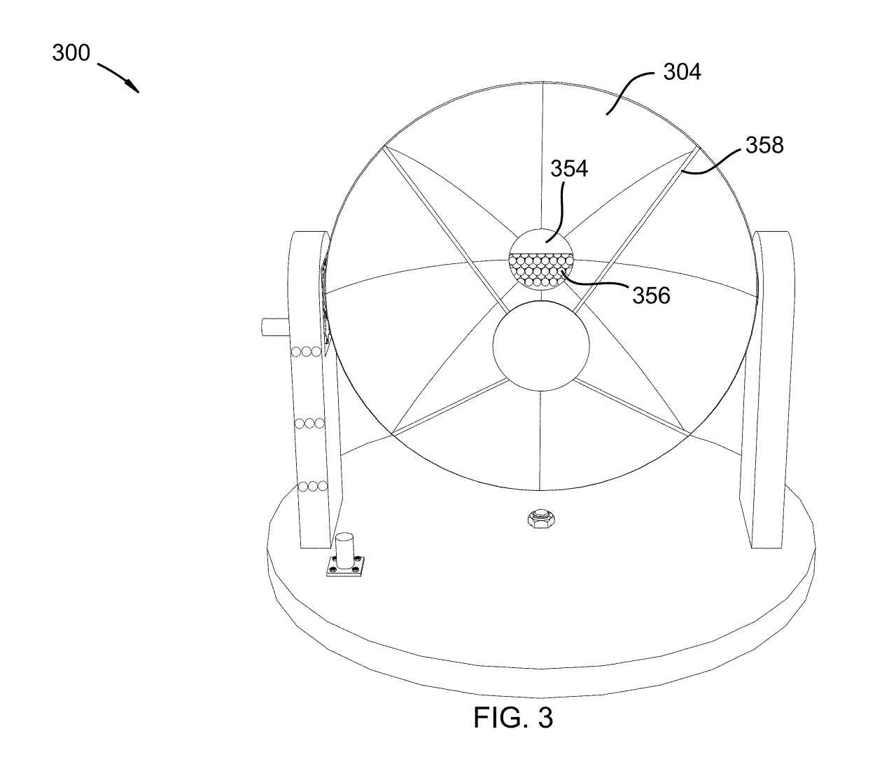

FIG. 3 shows a solar energy device 300 including first parabolic reflector 304, second parabolic reflector 306, shutter 354, and heat retaining materials 356. Heat retaining materials 356 may be water, brick, metal, metal micro-beads, ceramic, material with a density greater than 0.9, or any combination thereof. Heat retaining materials 356 may be found inside of heat exchangers 110/210. An optical lens or other optical element such as a diffuser, cover glass, or optically transparent material may be positioned as an optical cover allowing light energy to penetrate into first heat exchangers 110/210. Heat exchangers 110/210 may be direct contact heat exchangers directly heating a heat transfer fluid in addition to heating heat retaining materials 356. Heat transfer fluids such as forced air, water, glycol, etc. may be used to remove heat from heat transfer materials 356 and move the heat to another location or to directly heat one or more spaces or objects.

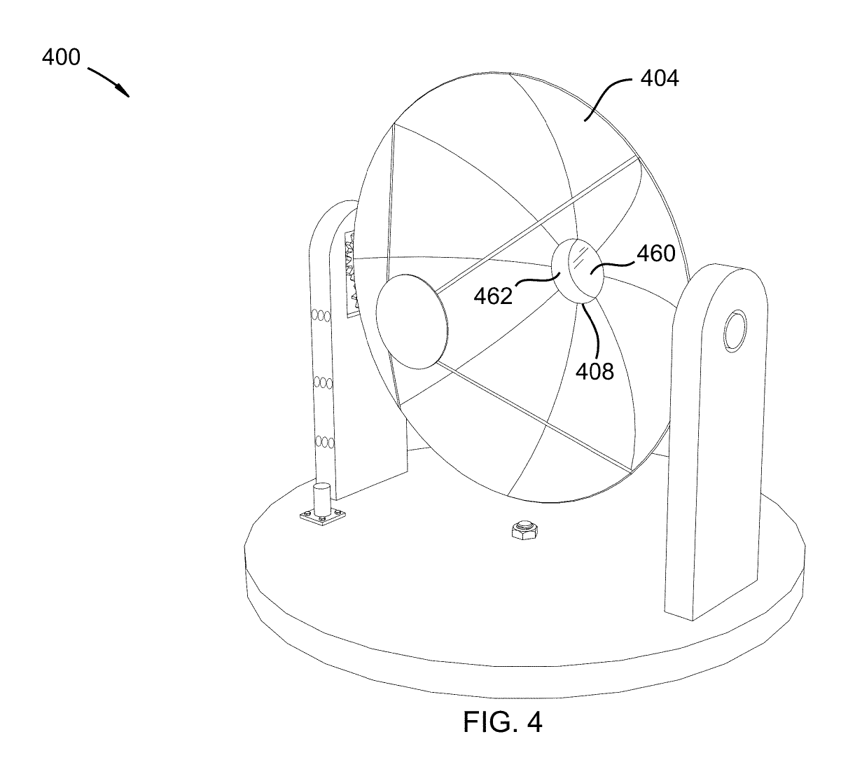

FIG. 4 shows a solar energy device 400 including optical element 460, aperture 408, and gap 462. Gap 462 allows a shutter to be positioned between optical element 460 and aperture 408 of first parabolic reflector 404 while also creating a separation from heat within a heat exchanger and the first parabolic reflector 404.

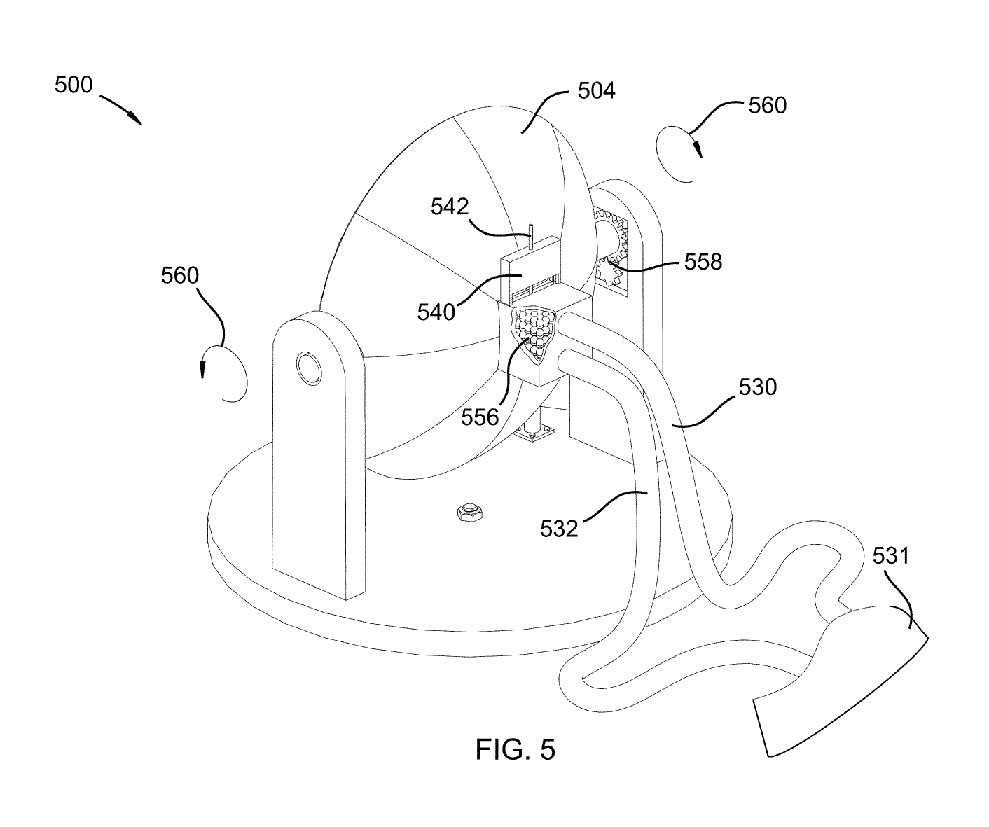

FIG. 5 shows a solar energy device 500 including shutter housing 540, shutter actuator rod 542, heat transfer lines 530/532, first parabolic reflector 504. Heat retaining materials 556 may be water, brick, metal, metal micro-beads, ceramic, material with a density greater than 0.9, or any combination thereof. Heat retaining materials 556 may be found inside of first heat exchangers and second heat exchangers. Shutter rod 542 may be used to control heat inside of first heat exchanger and/or the second heat exchanger. Another method of controlling heat may be to rotate the first parabolic reflector away from incident sunlight in a vertical rotation 560 or a horizontal rotation by the base. Heat transfer fluids such as forced air, water, glycol, etc. may be used to remove heat from heat transfer materials 556 and move the heat to another location by way of heat transfer lines 532/530. Heat transfer lines 530/532 may be connected to a barbeque grill, smoker, dehydrator, kettle, pot, coffee maker, stove, toaster oven, pizza oven, bread oven, warmer, steam cooker, solar still, incubator, kiln, sanitizer cabinet, or an autoclave 531. In some embodiments, controlled temperature unit 531 may be generally thought of as a food container.

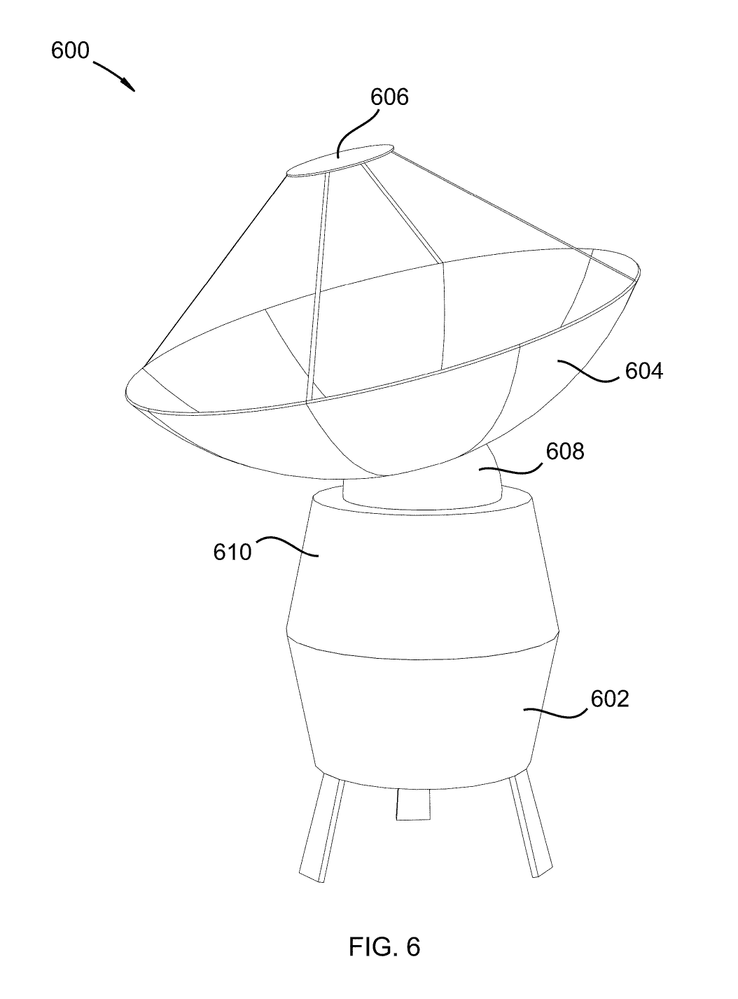

FIG. 6 shows a solar energy device 600 including a heated container 602, a heated container lid 610, a joint 608, first parabolic reflector 604, and second parabolic reflector 606. Heated container 602 may be a barbeque grill, smoker, dehydrator, stove, toaster oven, pizza oven, bread oven, warmer, steam cooker, solar still, incubator, kiln, sanitizer cabinet, or an autoclave. In some embodiments, heated container 602 may be generally thought of as a food container. Heated container 602 may include a temperature thermometer and one or more mechanical vents for adjusting the temperature within the container. First parabolic reflector 604 may be made of light weight reflective materials such as plastic, Mylar, carbon fibers, fiber class, aluminum, or glass.

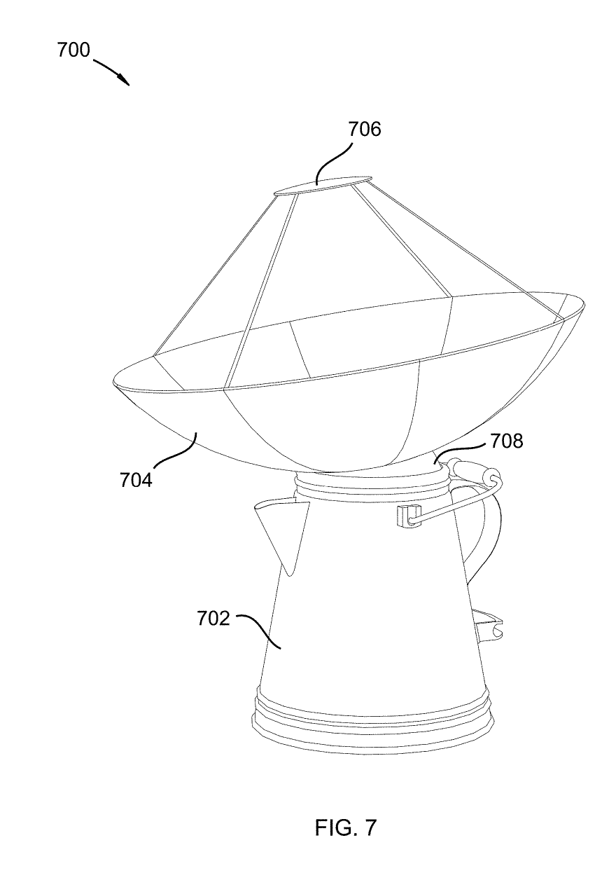

FIG. 7 shows a solar energy device 700 including a heated container 702, a heated container lid with a moving joint 708, first parabolic reflector 704, and second parabolic reflector 706. Heated container 702 may be a kettle, coffee maker, tea pot, barbeque grill, smoker, dehydrator, stove, toaster oven, pizza oven, bread oven, warmer, steam cooker, solar stil, incubator, kiln, sanitizer cabinet, or an autoclave. In some embodiments, heated container 702 may be generally thought of as a liquid food container. Heated container 702 may include a temperature thermometer and one or more mechanical vents for adjusting the temperature within the container. First parabolic reflector 704 may be made of light weight reflective materials such as plastic, Mylar, carbon fibers, fiber class, aluminum, or glass.

The first and second parabolic reflector lid assemblies of FIGS. 6 and 7 may additionally be used to start fires. If the lid portion, (including the first and second parabolic reflectors), were removed and placed over ignitable material a fire would readily start.

The systems and methods disclosed herein may be embodied in other specific forms without departing from their spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A solar device comprising:
a first parabolic reflector;
a second parabolic reflector;
wherein the first parabolic reflector reflects sunlight into the second parabolic reflector and the second parabolic reflector reflects substantially all of the sunlight through an opening in the first parabolic reflector and
wherein the first parabolic reflector is mechanically connected to a cooking device, a sterilizer device, a purification device, a heat transfer device, or an incubator.

2. The solar device of claim 1, further comprising a heat exchanger.

3. The solar device of claim 2, wherein the heat exchanger contains material for retaining, storing, or transferring heat.

4. The solar device of claim 1, wherein the solar device is used to cook food, heat water, or sterilize water.

5. The solar device of claim 1, wherein the solar device is used to sterilize objects.

6. The solar device of claim 1, further comprising one or more heat transfer lines.

7. The solar device of claim 1, wherein the first parabolic reflector is larger in overall size than the second parabolic reflector.

8. The solar device of claim 1, wherein the first solar reflector tracks the sunlight such that temperature within a heat exchanger is controlled.

9. The solar device of claim 8, wherein the tracking is 2-axis tracking.

10. The solar device of claim 1, wherein the first solar reflector is attached to a rotating base and two side supports, the rotating base forming a first axis of rotation and the two side supports forming a second axis of rotation.

11. The solar device of claim 10, wherein each axis of rotation is independently controlled by a first motor and a second motor.

12. The solar device of claim 11, wherein the first motor or the second motor is rotated to control a temperature within the heat exchanger.

13. The solar device of claim 1, wherein the mechanical connection attaches to: a barbeque grill, a smoker, a dehydrator, a kettle, a pot, a coffee maker, a stove, a toaster oven, a pizza oven, a bread oven, a warmer, a steam cooker, a solar still, an incubator, a kiln, a sanitizer cabinet, or an autoclave.

14. The solar device of claim 2, wherein the heat exchanger forms a surface for cooking.

15. The solar device of claim 1, further comprising a cooking container.

16. The solar device of claim 1, wherein the solar device provides heat for cooking, purifying water, sanitizing, or starting fires.

17. The solar device of claim 2, further comprising a shutter between the first parabolic reflector and the heat exchanger.

18. The solar device of claim 2, further comprising an optically transparent element behind, inside, or near the opening in the first parabolic reflector.

19. The solar device of claim 2, wherein the heat exchanger is a cooking container.

20. The solar device of claim 14, wherein the mechanical connection attaches to a lid of a cooking container.
